(19) United States
(12) Patent Application Publication
(10) Pub. No.: US 2023/0411926 A1
(43) Pub. Date: Dec. 21, 2023

(54) MULTI-WAFER INTEGRATED VCSEL-ELECTRONICS MODULE

(71) Applicant: Sense Photonics, Inc., Durham, NC (US)

(72) Inventors: Tarek AL ABBAS, Edinburgh (GB); Jamie STOKES, Linlithgow (GB); Neil CALDER, Edinburgh (GB); Hod FINKELSTEIN, Berkeley, CA (US); Scott BURROUGHS, Raleigh, NC (US)

(21) Appl. No.: 18/252,376

(22) PCT Filed: Nov. 23, 2021
(86) PCT No.: PCT/US2021/060431

§ 371 Date: May 10, 2023

Related U.S. Application Data
(60) Provisional application No. 63/117,111, filed on Nov. 23, 2020.

(51) Int. Cl. H01S 5/042; H01S 5/42; H01S 5/0239

(52) U.S. Cl. CPC H01S 5/04256; H01S 5/423; H01S 5/0239

(57) ABSTRACT

An illumination apparatus includes a first semiconductor layer comprising a plurality of emitters that are electrically interconnected in or on the first semiconductor layer, and a second semiconductor layer that is bonded to the first semiconductor layer in a stacked arrangement. The second semiconductor layer comprises a plurality of transistors that are electrically connected to respective emitters or subsets of the plurality of emitters at a bonding interface between the first and second semiconductor layers. Related systems and methods of fabrication are also discussed.

### CLAIM OF PRIORITY

This application claims priority from U.S. Provisional Patent Application Ser. No. 63/117,111, filed Nov. 23, 2020, the disclosure of which is incorporated by reference herein in its entirety.

### FIELD

The present invention relates to semiconductor-based light emitting devices and related devices and methods of operation.

### BACKGROUND

Many emerging technologies, such as Internet-of-Things (IoT) and autonomous navigation, may involve detection and measurement of distance to objects in three-dimensional (3D) space. For example, automobiles that are capable of autonomous driving may require 3D detection and recognition for basic operation, as well as to meet safety requirements. 3D detection and recognition may also be needed for indoor navigation, for example, by industrial or household robots or toys.

Light based 3D measurements may be superior to radar (low angular accuracy, bulky) or ultra-sound (very low accuracy) in some instances. For example, a light-based 3D sensor system may include a detector (such as a photodiode or camera) and a light emitting device (such as a light emitting diode (LED) or laser diode) as light source, which typically emits light outside of the visible wavelength range. A vertical cavity surface emitting laser (VCSEL) is one type of light emitting device that may be used in light-based sensors for measurement of distance and velocity in 3D space. Arrays of VCSELs may allow for power scaling and can provide very short pulses at higher power density.

For example, arrays of VCSELs may increasingly be used to illuminate a field of view in solid state light detection and ranging (LiDAR or lidar) systems, as VCSEL arrays may allow electronically-controlled flash and/or scanning of a scene without the need for mechanically-controlled scanning (e.g., using microelectromechanical systems (MEMs) or other mechanical scanning systems). The VCSELs may be integrated on a single integrated circuit chip or “die,” or as separate discrete VCSELs connected in an array.

As VCSEL processing costs are reduced and VCSEL technology is further developed, sizes of the VCSEL arrays may increase, both in terms of the number of VCSELs per array and the dimensions of the die containing the VCSEL array. A die or chip may refer to a small block of semiconducting material or other substrate on which electronic circuit elements are fabricated (e.g., as diced or otherwise separated from a larger semiconductor wafer, a process referred to herein as singulation).

The VCSEL control circuits (e.g., driver circuits) and the VCSELs may generally be located on separate integrated circuit (IC) dies or printed circuit boards (PCBs), which may increase cost, circuit area, and device thickness. VCSEL arrays may be flip-chip bonded onto substrates adjacent to complementary metal-oxide-semiconductor (CMOS) driver and fan-out circuitries with off-sited bonding contacts, but this may likewise be expensive and/or difficult to scale for high-volume production.

### SUMMARY

Some embodiments described herein are directed to emitter elements, including light emitting diodes or laser diodes, such as surface- or edge-emitting laser diodes or other semiconductor lasers, and arrays incorporating the same. In some embodiments, a laser diode may be a surface-emitting laser diode, such as a VCSEL. The laser diode includes a semiconductor structure comprising an n-type layer (such as a Bragg reflector), an active region (which may comprise at least one quantum well layer), and a p-type layer (such as a Bragg reflector). One of the n-type and p-type layers comprises a lasing aperture thereon having an optical axis oriented perpendicular to a surface of the active region between the n-type and p-type layers. The laser diode further includes first and second contacts electrically connected to the n-type and p-type layers, respectively, e.g., anode and cathode contacts.

According to some embodiments, an illumination apparatus includes a first semiconductor layer (e.g., a first semiconductor die or a first semiconductor wafer including a plurality of dies) that is bonded with a second semiconductor layer (e.g., a second semiconductor die or a second semiconductor wafer including a plurality of dies) in a stacked arrangement. The first semiconductor layer includes a plurality of emitters that are electrically interconnected in or on the first semiconductor layer. The second semiconductor layer includes a plurality of transistors (e.g., defining driver integrated circuits, also referred to herein as driver ICs). The plurality of transistors are electrically connected to respective emitters or subsets of emitters at a bonding interface between the first and second semiconductor layers.

In some embodiments, the bonding interface may include first and second contacts (e.g., anode and/or cathode connections) to the respective emitters or subsets. For example, the anode and/or cathode connections may be exposed at the bonding interface between the first and second semiconductor layers. The transistors may define respective control circuits that are electrically connected to the anode and/or cathode connections.

In some embodiments, the respective control circuits may include driver circuits. Each of the driver circuits may be electrically connected to the anode or cathode connections of the respective emitters or subsets at the bonding interface.

In some embodiments, the respective emitters or subsets may be electrically interconnected by array interconnects to define a two-dimensional array of the respective emitters or subsets. The driver circuits may define a two-dimensional array of the driver circuits that are electrically connected to the two-dimensional array of the respective emitters or subsets, respectively, at the bonding interface.

In some embodiments, the emitters may be VCSELs and the first semiconductor layer may be a VCSEL array wafer. In some embodiments, the transistors may be driver circuits and the second semiconductor layer may be a driver IC wafer including an array of driver circuits, for example, with one driver circuit per VCSEL or subset/cluster of VCSELs. The VCSEL array wafer may be stacked on and bonded to the driver IC wafer using wafer-to-wafer hybrid bonding.

In some embodiments, a signal distribution circuit may be electrically connected to the driver circuits and may be configured to control timings of respective drive signals output from the driver circuits. The signal distribution circuit may be included in the second semiconductor layer or in a third semiconductor layer that may be stacked and bonded to the second semiconductor layer.

In some embodiments, an addressing circuit may be configured to address the driver circuits to individually select one of the respective emitters or subsets at a time. For example, the addressing circuit may be configured to individually select driver ICs coupled to a VCSEL or subset/cluster of VCSELs. The addressing circuit may be included in the second semiconductor layer or in a third semiconductor layer that may be stacked and bonded to the second semiconductor layer.

In some embodiments, the respective control circuits of the second semiconductor layer may include the signal distribution circuit and/or the addressing circuit.

In some embodiments, one or more additional circuits may be configured to provide localized decoupling capacitance, power supply routing, and/or other control of the respective emitters or subsets. The one or more additional circuits may be in the second semiconductor layer or is in a third semiconductor layer that is stacked on and bonded to the second semiconductor layer opposite the first semiconductor layer.

In some embodiments, the first and second semiconductor layers may be bonded by hybrid bonding, through via connections, and/or bump-bonding. For example, the bonding interface may include hybrid bonding, through vias, and/or bump-bonds that electrically connect the anode and/or cathode connections to the control circuits and/or to an electrical ground.

In some embodiments, the array interconnects may electrically connect the subsets within the first semiconductor layer in series or parallel with respective interconnection lengths of less than about 10 microns.

In some embodiments, the first and second semiconductor layers may be first and second semiconductor wafers that are bonded to one another, wherein the plurality of emitters are native to the first semiconductor wafer and the plurality of transistors are native to the second semiconductor wafer.

In some embodiments, the first and second semiconductor layers may be singulated portions of first and second semiconductor wafers that are bonded to one another and define respective integrated emitter-electronics structures.

In some embodiments, the transistors may be directly connected with the anodes and/or cathode connections of the respective emitters or subsets at the bonding interface.

In some embodiments, the bonding interface may include one or more interposer or redistribution layers between the first and second semiconductor layers.

In some embodiments, the first semiconductor layer may be between the emitters and the bonding interface, and the emitters may include respective lasing apertures that are opposite the first semiconductor layer.

In some embodiments, the emitters may be between the first semiconductor layer and the bonding interface, and the emitters may include respective lasing apertures that are facing the first semiconductor layer.

According to some embodiments, a method of fabricating an illumination apparatus includes providing a first semiconductor layer comprising a plurality of emitters that are electrically interconnected in or on the first semiconductor layer; providing a second semiconductor layer comprising a plurality of transistors; and bonding the second semiconductor layer to the first semiconductor layer in a stacked arrangement such that the transistors are electrically connected to respective emitters or subsets of the plurality of emitters at a bonding interface between the first and second semiconductor layers.

In some embodiments, the first and second semiconductor layers may be first and second semiconductor wafers that are bonded to one another. The plurality of emitters may be native to the first semiconductor wafer and the plurality of transistors may be native to the second semiconductor wafer.

In some embodiments, the method further includes singulating bonded portions of the first and second semiconductor layers into respective integrated emitter-electronics structures. The second semiconductor wafer may be thinned prior to the bonding in some embodiments.

In some embodiments, the portions of the first and/or second semiconductor layers may include respective lift-off structures. The method may further include transfer-printing one or more of the respective integrated emitter-electronics structures on a third substrate that is non-native to the emitters and/or transistors. The third substrate may include electrical interconnects thereon in some embodiments.

In some embodiments, the bonding interface may include anode and/or cathode connections to the respective emitters or subsets, and the transistors may define respective control circuits that are electrically connected to the anode and/or cathode connections.

In some embodiments, the respective control circuits may include driver circuits, and each of the driver circuits may be electrically connected to the anode or cathode connections of the respective emitters or subsets at the bonding interface.

In some embodiments, the respective emitters or subsets may be electrically interconnected by array interconnects to define a two-dimensional array of the respective emitters or subsets, and the driver circuits may define a two-dimensional array of the driver circuits that are electrically connected to the two-dimensional array of the respective emitters or subsets, respectively, at the bonding interface.

In some embodiments, the respective control circuits may include a signal distribution circuit that is electrically connected to the driver circuits and is configured to control timings of respective drive signals output from the driver circuits.

In some embodiments, the respective control circuits may include an addressing circuit that is configured to address the driver circuits to individually select one of the respective emitters or subsets at a time.

In some embodiments, the method may include providing one or more additional circuits configured to provide localized decoupling capacitance, power supply routing, and/or other control of the respective emitters or subsets. The one or more additional circuits may be in the second semiconductor layer or may be in a third semiconductor layer that is stacked on and bonded to the second semiconductor layer opposite the first semiconductor layer.

In some embodiments, the bonding may include hybrid bonding, through vias, and/or bump-bonds at the bonding interface to electrically connect the anode and/or cathode connections to the control circuits and/or to an electrical ground.

In some embodiments, the array interconnects may electrically connect the subsets within the first semiconductor layer in series or parallel with respective interconnection lengths of less than about 10 microns.

In some embodiments, the bonding may include directly connecting the transistors with the anodes and/or cathode connections of the respective emitters or subsets at the bonding interface.

In some embodiments, the bonding may include bonding the second semiconductor layer to the first semiconductor layer with one or more interposer or redistribution layers between the first and second semiconductor layers.

Some embodiments described herein provide a lidar system including one or more emitter units (including one or more semiconductor lasers, such as surface- or edge-emitting laser diodes; generally referred to herein as emitters, which output emitter signals), one or more light detector pixels (including one or more photodetectors, such as semiconductor photodiodes, including avalanche photodiodes and single-photon avalanche detectors; generally referred to herein as detectors, which output detection signals in response to incident light), and one or more control circuits that are configured to selectively operate subsets of the emitter units and/or detector pixels (including respective emitters and/or detectors thereof, respectively) to provide a 3D time of flight (ToF) flash lidar system.

Other devices, apparatus, and/or methods according to some embodiments will become apparent to one with skill in the art upon review of the following drawings and detailed description. It is intended that all such additional embodiments, in addition to any and all combinations of the above embodiments, be included within this description, be within the scope of the invention, and be protected by the accompanying claims.

### BRIEF DESCRIPTION OF THE DRAWINGS

FIG. 1 is a schematic diagram illustrating bonding of emitter semiconductor layers with transistor semiconductor layers according to some embodiments of the present invention.

FIGS. 2A, 2B, and 2C are schematic cross-sectional views illustrating example stacked configurations of driver semiconductor layers including driver circuits and emitter semiconductor layers including arrays of emitters in accordance with some embodiments of the present invention.

FIGS. 3A, 3B, and 3C are schematic circuit diagrams illustrating example interconnections of respective emitters within an emitter semiconductor layer in accordance with some embodiments of the present invention.

FIGS. 4, 5, and 6 are schematic circuit diagrams illustrating example configurations of control circuit elements coupled to the transistors of a semiconductor layer or wafer in accordance with some embodiments of the present invention.

FIG. 7 is a schematic cross-sectional view illustrating an emitter wafer and a transistor wafer in a stacked and bonded arrangement in greater detail.

FIG. 8A is a schematic cross-sectional view illustrating an illumination apparatus including an integrated frontside illumination (FSI) VCSEL array and stacked driver IC configuration in accordance with some embodiments of the present invention.

FIG. 8B is a schematic cross-sectional view illustrating an illumination apparatus including an integrated backside illumination (BSI) VCSEL array and stacked driver IC configuration in accordance with some embodiments of the present invention.

FIG. 9A is a schematic cross-sectional view illustrating an illumination apparatus including an integrated FSI VCSEL structure in accordance with a comparative example.

FIG. 9B is a schematic cross-sectional view illustrating an illumination apparatus including an integrated BSI VCSEL structure in accordance with a comparative example.

### DETAILED DESCRIPTION

In the following detailed description, numerous specific details are set forth to provide a thorough understanding of embodiments of the present disclosure. However, it will be understood by those skilled in the art that the present disclosure may be practiced without these specific details. In some instances, well-known methods, procedures, components, and circuits have not been described in detail so as not to obscure the present disclosure. It is intended that all embodiments disclosed herein can be implemented separately or combined in any way and/or combination. Aspects described with respect to one embodiment may be incorporated in different embodiments although not specifically described relative thereto. That is, all embodiments and/or features of any embodiments can be combined in any way and/or combination.

In some LiDAR applications, addressing of separate emitters (e.g., VCSELs) or clusters of emitters in an emitter array may be utilized to illuminate or interrogate only particular target(s) of interest within an overall field of view of the emitter array, which may significantly reduce emitter power compared to continually illuminating the full field of view. As such, it may be desirable to address clusters of emitters within the emitter array to facilitate emitter-to-detector pixel (or emitter cluster-to-detector pixel cluster) synchronization. This may require relatively dense interconnects between the drivers and emitters.

Arrays of VCSELs or other emitters may be also subject to parasitic impedances (resistance, inductance and capacitance) of interconnections between the distributed emitters and the discrete driver circuitry. For example, parasitic resistances, capacitances and/or inductances associated with the connectivity between a VCSEL array and driver circuits may limit rise and fall times (as well as pulse widths) of the VCSEL outputs. Additionally, the control of the emitters at different physical locations within the array may be challenging due to unequal impedances of the respective interconnects between emitters or sub-arrays of emitters.

Embodiments of the present invention are directed to various emitter technologies manufactured on wafers (including LEDs and laser diodes, primarily described herein with reference to VCSELs by way of example), as well as various electrical circuit or transistor technologies which are manufactured on different wafers, (including CMOS, BiCMOS, Sapphire, Silicon-on-Insulator, RF CMOS, GaN FET, etc., primarily described herein with reference to CMOS by way of example). In particular, some embodiments of the present invention may include a first semiconductor layer (e.g., a first semiconductor die or a first semiconductor wafer) including a plurality of emitters (e.g., laser diodes, such as VCSELs) electrically interconnected within the first semiconductor layer, with the first semiconductor layer bonded with a second semiconductor layer (e.g., a second semiconductor die or a second semiconductor wafer) including control circuits (e.g., driver transistors). The first and second semiconductor layers may be bonded to one another (e.g., using hybrid bonding, through vias, bump-bonding etc.) to electrically connect the control circuits or transistors to respective emitters or subsets of emitters (including serially connected sub-arrays or parallel-connected sub-arrays of emitters). The control circuits (e.g., driver transistors) may be directly connected with the anode and/or cathodes of respective emitters (or sub-arrays of emitters) by electrical connections at the bonding interface, or one or more interposer or redistribution layers may be provided between the first and second semiconductor layers.

The first semiconductor layer (in which the emitters and interconnects are formed) may be a different material than the second semiconductor layer (in which the drive or other control circuitry is formed), and hybrid material bonding processes may be used to bond the first semiconductor layer to the second semiconductor layer, allowing for heterogeneous integration. Hybrid bonding can be used to bond two structures together using different materials, for example, two wafers together (wafer-to-wafer bonding) and a chip to a wafer (die-to-wafer bonding). For example, the two wafers may be bonded together using a combination of two technologies, e.g., a dielectric-to-dielectric and a metal-to-metal bond, thereby stacking and connecting devices in the respective wafers directly using fine-pitch (e.g., copper) connections, rather than microbumps and pillars.

Wafer-to-wafer bonding may be used in some embodiments described herein to reduce or minimize interconnection lengths (and thus parasitic impedances) between emitters and control (e.g., driver) circuits. The emitters may be electrically connected at the wafer-level (i.e., on or within the wafer or semiconductor layer in which the emitters are formed, also referred to herein as a native wafer or substrate) by a dense interconnection arrangement, also referred to herein as array interconnections or array interconnects, which may provide series or parallel interconnections with electrical interconnects between adjacent emitters on the order of microns (e.g., less than about 10 microns, less than about 5 microns, or less than about 2 microns) throughout the wafer. In contrast, die-level interconnects are typically provided at peripheral or edge regions of a die, and may be significantly larger (e.g., on the order of tens of microns or more), increasing parasitic impedance issues.

As such, in embodiments of the present invention, the emitter arrays and the control circuit (e.g., driver) arrays may be stacked to electrically connect one or more two-dimensional (2D) arrays of driver circuits with one or more 2D arrays of emitters, with greater area density (provided by the array interconnections between devices on or within the respective semiconductor layers) and reduced interconnection lengths (provided by the electrical connections at the bonding interface). The stacked/bonded first and second semiconductor layers including the emitters and driver circuitry, respectively, may be subsequently singulated (e.g., by dicing) to define illumination apparatus or emitter arrays with stacked/integrated driver circuitry. The singulation may be performed to define emitter arrays with a desired array resolution or number of pixels.

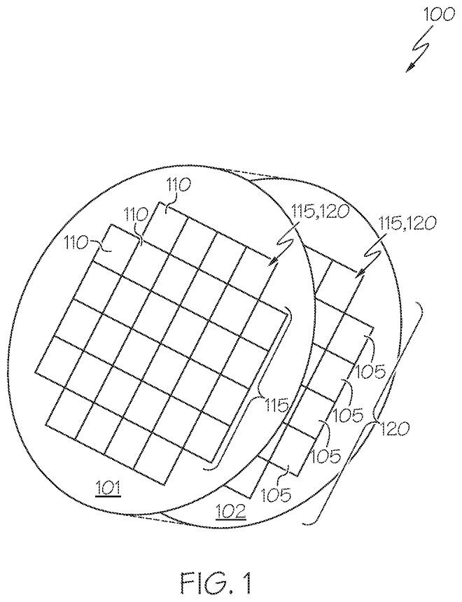

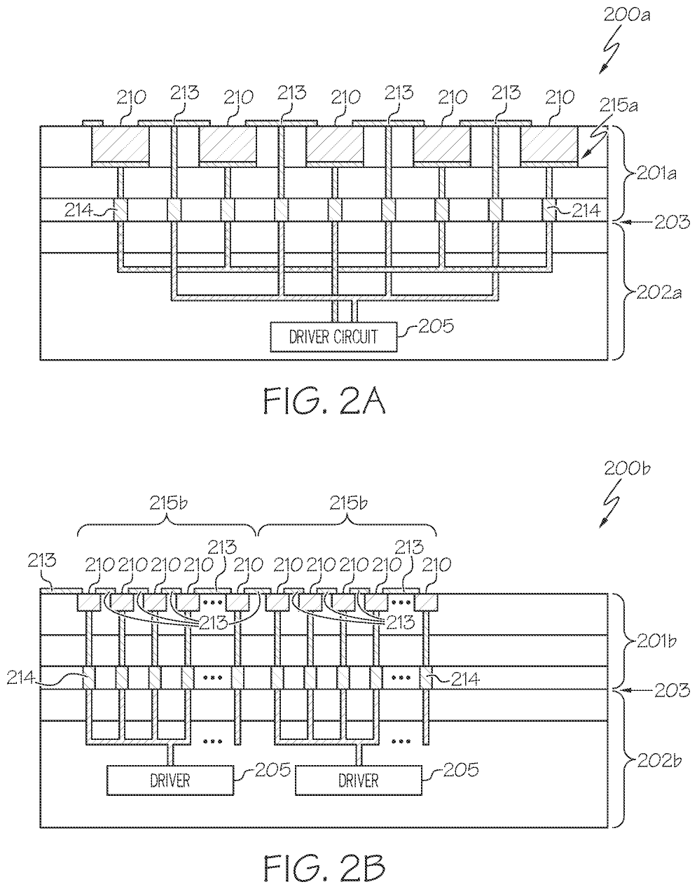

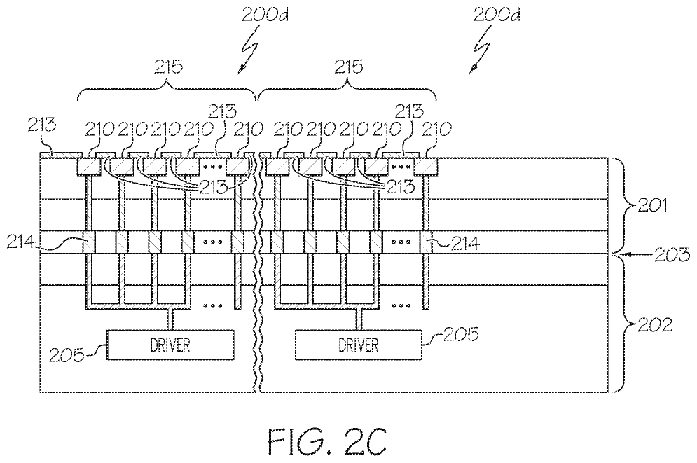

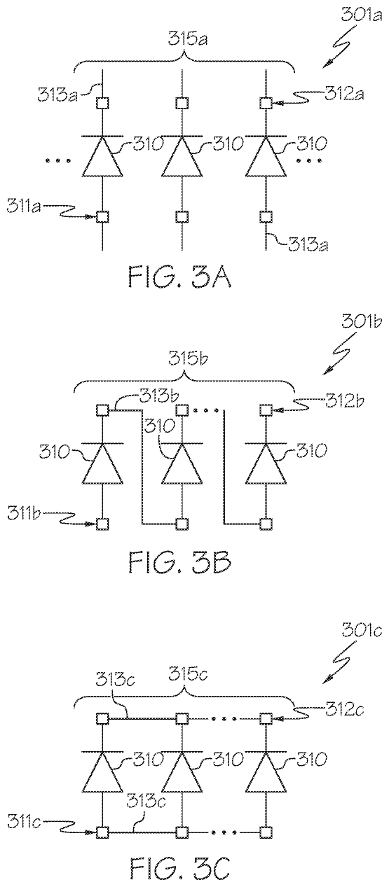

FIG. 1 is a schematic diagram illustrating bonding of emitter semiconductor layers (shown by way of example as VCSEL wafers) with transistor semiconductor layers (shown as silicon CMOS wafers) in a stacked configuration 100 according to some embodiments of the present invention. FIGS. 2A and 2B are cross-sectional views illustrating example stacked configurations 200a and 200b of wafers including driver circuits and arrays of emitters (shown by way of example as VCSELs) in accordance with some embodiments of the present invention. FIG. 2C is a cross-sectional view illustrating dies 200d singulated from the bonded wafers of FIG. 2B. FIGS. 3A to 3C are schematic circuit diagrams illustrating example interconnections of respective emitters 310 (shown by way of example as VCSELs) within the emitter semiconductor layer.

Although described/illustrated primarily with reference to transistors or drive circuitry provided in a silicon (Si) wafer, it will be understood that the transistor semiconductor layer(s) or wafer (also referred to herein as a second device layer or wafer) may be Group-III nitride (e.g., gallium nitride (GaN))-based or GaN on silicon carbide (SiC) in some embodiments. Also, the transistor semiconductor layers may be gallium arsenide (GaAs)-based or indium phosphide (InP)-based in some embodiments, for example, to provide higher mobility transistors for ultra-high speed performance.

Likewise, the emitter semiconductor layer(s) or wafer (also referred to herein as a first device layer or wafer) may be formed of materials that are selected to define the light emission output from the emitters at or over a desired wavelength range. In some example embodiments, the first device layer or wafer may include an InP-based structure. In particular embodiments, the active region may include one or more InP-based layers (for example, a multi-quantum well (MQW) active region including alternating InGaAsP/InP or AlGaInAs/InP layers), which are configured to emit light having a wavelength of about 1400 nanometers to about 1600 nanometers. In further example embodiments, the first device layer or wafer may be GaN-based structure. The emitter and drive circuitry semiconductor layers may thus be formed of the same or different semiconductor materials.

As shown in FIGS. 1 and 2A-2B, a first device layer or wafer 101, 201a, 201b including sets or arrays 115, 215a, 215b of emitters 110, 210 (e.g., VCSELs) and a second device layer or wafer 102, 202a, 202b including corresponding sets 120 of driver circuits 105, 205 are separately fabricated, stacked, and bonded such that the driver circuits 105, 205 are electrically connected with the anode and/or cathodes of respective arrays of VCSELs 110, 210 at the bonding interface 203 therebetween. In particular, as shown in FIGS. 2A and 2B, the first device layer or wafer 201a, 201b (generally referred to as 201) may include one or more semiconductor sublayers defining one or more VCSELs 110, 210, for example, in sets or arrays 215a, 215b of 1 to N VCSELs (where N is an integer indicating the number of VCELs 210 in the set or array 215a, 215b; generally referred to as 215), which may be diced or otherwise separated into respective VCSEL dies. The second device layer or wafer 202a, 202b (generally referred to as 202) may include one or more semiconductor sublayers defining one or more driver circuits 205, which may likewise be diced or otherwise separated into respective driver circuit dies.

The VCSELs 110, 210 may be native to the first device layer or wafer 101, 201, and may be electrically connected at the wafer-level on or within the first device layer or wafer 101, 201, for example, by array interconnects 213 therebetween. As shown in FIG. 2A respective interconnects 213 electrically connect anodes and/or cathodes of adjacent VCSELs of the 1 to N VCSELs on the first device layer 201a, opposite the bonding interface 203. The first device layer or wafer 101, 201 further includes anode and/or cathode connections 214 to respective VCSELs 110, 210 of or (subsets of VCSELs of) the 1 to N VCSELs 215a, 215b at the bonding interface 203 with the second device layer or wafer 102, 202a, 202b.

For example, in some embodiments as shown in FIG. 3A, the array interconnects 313a may provide individual electrical connections to the anode 311a and cathode 312a of each VCSEL 310 of the 1 to N VCSELs 315a within the first semiconductor layer or wafer 301a (also referred to herein as a device wafer). In some embodiments as shown in FIG. 3B, the array interconnects 313b may electrically connect the VCSELs 310 of the 1 to N VCSELs 315b in series sub-arrays (e.g., cathode 312b-to-anode 311b) within a first device wafer 301b. In some embodiments as shown in FIG. 3C, the array interconnects 313c may electrically connect the VCSELs 310 of the 1 to N VCSELs 315c in parallel sub-arrays (e.g., anode 311c-to-anode 311c and cathode 312c-to-cathode 312c) within a first device wafer 301c. The array interconnects may provide the series or parallel electrical connections between adjacent VCSELs 310 with respective interconnection lengths on the order of microns (e.g., less than about 10 microns, less than about 5 microns, or less than about 2 microns).

Referring again to FIGS. 2A and 2B, as noted above, the second device layer or wafer 202 may include one or more semiconductor sublayers defining one or more driver circuits 205 (CMOS or otherwise), which may also be diced or otherwise separated into respective driver circuit dies. FIG. 2A illustrates electrical connections between a single driver circuit 205 of the second device wafer 202a and an array of 1 to N VCSELs 215a of the first device wafer 201a. FIG. 2B illustrates electrical connections between multiple driver circuits 205 of the second device wafer 202b with respective arrays of 1 to N VCSELs 215b of the first device wafer 201b, e.g., one driver circuit 205 per VCSEL 210 or per VCSEL sub-array 215b.

The bonding interface 203 between the first device wafer 201a, 201b and the second device wafer 202a, 202b electrically connects the driver circuits 205 of the second device wafer 202a, 202b to the VCSELs 210/VCSEL sub-arrays 215a, 215b of the first device wafer 201a, 201b. For example, the bonding interface 203 may include one or more metallization layers and/or metal contacts that are configured to connect respective contacts of the first and second device wafers 201 and 202. Electrical connections may be made at or within the bonding interface 203 for both the anodes and cathodes of the VCSELs 210 (or VCSEL sub-arrays 215a, 215b), for example, to a driver circuit 205, a supply circuit, and/or associated circuits, dependent on the circuit configuration. Alternatively, one of the anodes or cathodes of the VCSELs 210 or VCSEL sub-arrays 215a, 215b may be connected to a supply or a driver circuit 205 at or within the bonding interface 203. The bonded first and second device wafers 201 and 202 shown in FIGS. 2A and 2B may be subsequently singulated to define respective dies 200d including VCSEL arrays 215 with integrated drive circuitry 205, as shown in FIG. 2C.

Referring again to FIGS. 1 and 2A-2B, in some embodiments, each driver circuit 105, 205 of the second device wafer 102, 202 is arranged and connected to control a VCSEL 110, 210 or array of N VCSELs 115, 215a, 215b. The driver circuits 105, 205 may be arranged parallel to the VCSEL 110, 210 or VCSEL array 115, 215a, 215b of the first device wafer 101, 201.

In some embodiments, the control circuit elements may not be limited to being provided in a single semiconductor layer or wafer, but rather may be distributed over multiple semiconductor layers or wafers, with the emitter semiconductor layer or wafer 101, 201 stacked thereon. For example, a third device wafer may be bonded to the second device wafer 102, 202. The third device wafer may include additional circuitry, for example, configured for localized decoupling capacitance, power supply routing, and/or other VCSEL/VCSEL array control. However, it will be understood that such additional decoupling circuitry may be fabricated in the second device wafer 102, 202 in some embodiments. More generally, while illustrated with reference to stacked arrangements of two semiconductor layers or wafers (one including emitter elements and the other including control circuit elements), it will be understood that embodiments of the present invention may include additional (e.g., three or more) semiconductor layers or wafers bonded and stacked, with electrical interconnections along respective bonding interfaces therebetween.

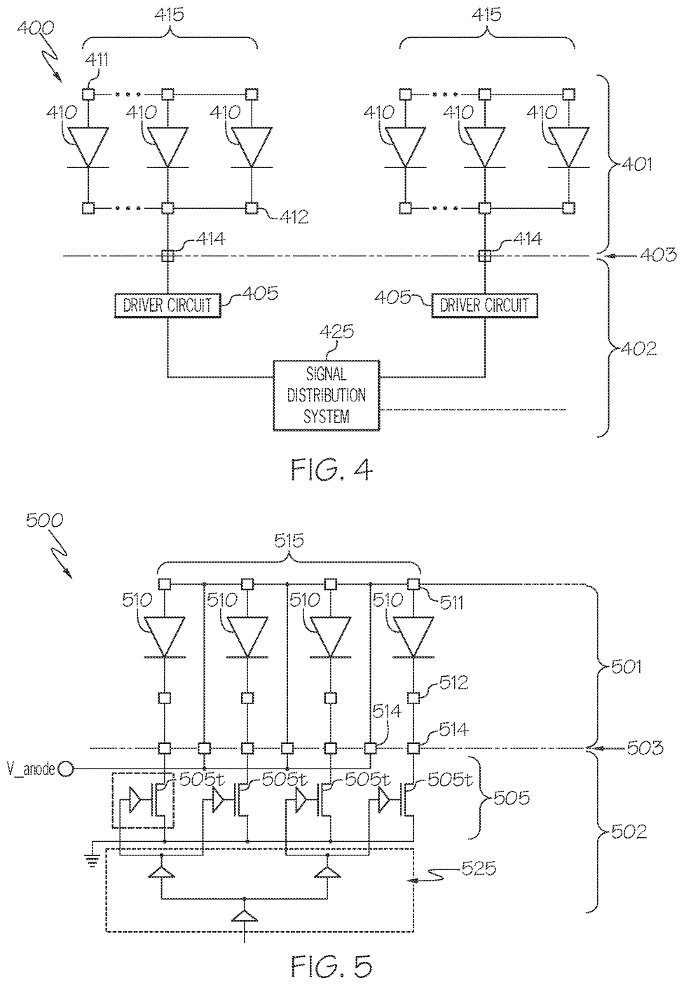

FIGS. 4 to 6 are schematic circuit diagrams illustrating example configurations of control circuit elements coupled to the transistors of the second device layer or wafer in accordance with some embodiments of the present invention. The control circuit elements in the examples of FIGS. 4 to 6 are implemented in the second device wafer with the transistors/drive circuitry, but it will be understood that one or more of the control circuit elements may be implemented in a different (e.g., a third) semiconductor layer or wafer that is stacked on and bonded to the second device wafer in some embodiments.

In some embodiments, the control circuit elements may define a signal distribution circuit that is connected to the driver circuits and is configured to control or set the timing of the control signals (also referred to as drive signals) output from the respective driver circuits. For example, as shown in the circuit diagram 400 of FIG. 4, a signal distribution circuit or system 425 may be implemented in the second device wafer (“Wafer 2”) 402 and electrically connected to the driver circuits 405 of second device wafer 402. In the example of FIG. 4, cathode connections 412 to respective subsets or sub-arrays (illustrated as two sub-arrays) of VCSELs 410 of a VCSEL array 415 implemented in the first device wafer (“Wafer 1”) 401 are provided by electrical connections 414 at the bonding interface 403 between Wafer 1 401 and Wafer 2 402. Respective driver circuits 405 (one for each VCSEL sub-array) of Wafer 2 402 are electrically connected to the cathode connections 412 by the connections 414 at the bonding interface 403, with the anode connections 411 of the VCSELs 410 of each sub-array electrically connected, e.g., to a supply voltage.

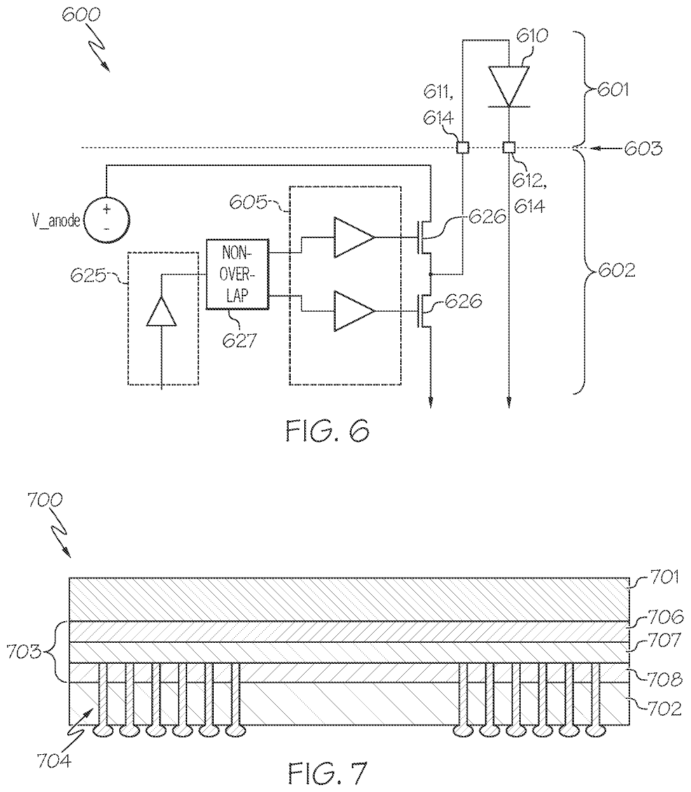

The signal distribution circuits or systems described herein may include buffer or other delay elements that are configured to match rise and fall times of output signals from VCSELs at different locations within the array. The circuit diagrams 500 and 600 of FIGS. 5 and 6 illustrate examples of the driver circuit 505, 605 and connections to signal distribution circuits 525, 625 as implemented in the same semiconductor layer or wafer (illustrated as Wafer 2) 502, 602 in greater detail.

As shown in FIG. 5, the driver circuits 505 are implemented as an array of transistors 505t in Wafer 2 502, which are coupled to cathode connections 512 of respective VCSELs 510 (or subsets/sub-arrays of VCSELs) of a VCSEL array 515 of Wafer 1 501 by electrical connections 514 at the bonding interface 503 between Wafer 1 501 and Wafer 2 502. A supply voltage (V_anode) is coupled to anode connections 511 of the respective VCSELs 510 (or subsets/sub-arrays of VCSELs) of the VCSEL array 515 by electrical connections 514 at the bonding interface 503. The driver circuits 505 are electrically connected to the cathode connections 512 of the VCSELs 510, also by respective connections 514 at the bonding interface 503, and are configured to selectively activate the respective VCSELs 510 (or subsets/sub-arrays of VCSELs) responsive to outputs of the signal distribution system 525 in Wafer 2 502.

As shown in FIG. 6, the driver circuits 605 are implemented in an alternative driver configuration (e.g., an H-bridge configuration) by respective CMOS transistor arrangements 626, which are coupled to anode connections 611 of respective VCSELs 610 (or subsets/sub-arrays of VCSELs) of a VCSEL array of Wafer 1 601 by electrical connections 614 at the bonding interface 603. Cathode connections 612 to the respective VCSELs 610 (or subsets/sub-arrays of VCSELs) are also provided at the bonding interface 603 and connected to an electrical ground through Wafer 2 602 (e.g., using one or more through via connections (also referred to herein as through vias) extending through Wafer 2) 602. The driver circuits 605 are configured to selectively activate the respective VCSELs 610 (or subsets/sub-arrays of VCSELs) by connecting the anode connections 611 to a supply voltage (V_anode) responsive to outputs of the signal distribution system 625 in Wafer 2 602. Circuit elements of Wafer 2 602 further define a non-overlap circuit 627 coupled between the signal distribution system 625 and the driver circuits 626.

In some embodiments, the control circuit elements in the second semiconductor layer or wafer may be configured to address the array of driver circuits to define which VCSEL/VCSEL arrays of the first semiconductor layer or wafer are driven at a particular time. For example, the control circuit elements may define an addressing circuit in the driver wafer that controls which VCSELs driver circuits/VCSELs are enabled. The addressing circuit(s) may be configured to allow for selective enabling or activation of VCSELs to be addressed simultaneously (individually, in subsets/clusters, or multiple/all in parallel).

In some embodiments, an integrated heat sink may be provided (e.g., using through-vias to an underlying PCB) in order to reduce the operating temperature of the VCSELs and allow for higher power operation, e.g., after singulation into a die format. FIG. 7 is a cross-sectional view illustrating an emitter wafer (e.g., a VCSEL wafer 701) and a transistor wafer (e.g., a CMOS wafer 702) in a stacked and bonded arrangement 700 in greater detail. In the example of FIG. 7, the bonding interface 703 is illustrated as including front end of line (FEOL) 708, back end of line (BEOL) 707, and metallization 706 portions. For example, a FEOL operation may define the CMOS wafer 702 with isolated transistors or driver circuits. A BEOL operation may implement one or more metallization layers 707 for fabrication of contacts (e.g., pads), interconnect wires, vias and/or dielectric structures, to which the metal connections 706 of the VCSEL wafer 701 (e.g., anode and/or cathode connections to respective VCSELs/subsets of VCSELs) may be stacked on and bonded. Additionally, the stacked VCSEL and CMOS wafers 700 may be post-processed (e.g., with through silicon vias) to provide connections to the VCSEL current loop, reducing IR drop and improving the thermal conductivity of the stacked die 700. In particular, as shown in FIG. 7, through vias 704 (e.g., through silicon vias (TSVs)) may be provided extending through the bottom of the CMOS (driver) wafer 702 to provide circuit connections (e.g., to a PCB), which may reduce voltage drop, reduce parasitics, and/or reduce inductance. The through vias 704 may also define a heat sink structure extending through the bottom of the CMOS (driver) wafer 702, which may improve thermal dissipation.

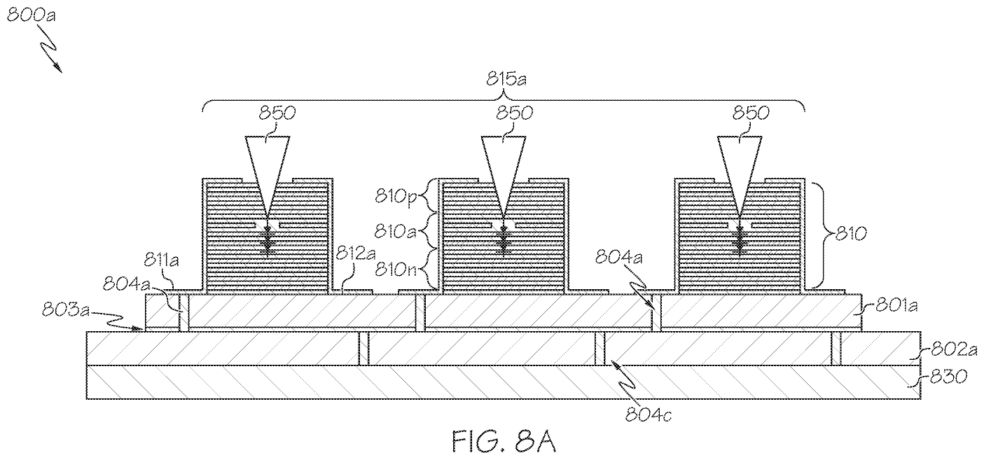

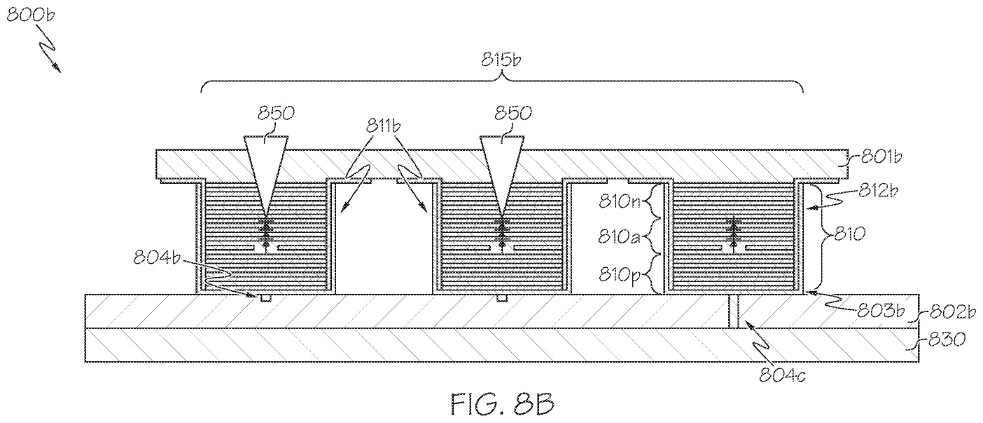

VCSELs or other surface-emitting laser diodes as described herein may have a semiconductor structure including an n-type layer and a p-type layer (e.g., implemented as a pair of distributed Bragg reflectors (DBRs)) with an active region (which may include one or more quantum well layers) therebetween. One of the n-type and p-type layers includes a lasing aperture having an optical axis oriented perpendicular to a surface of the active region. Anode and cathode contacts are electrically connected to the n-type and p-type layers, respectively, or vice versa. In the example illumination apparatus 800a and 800b shown in FIGS. 8A and 8B, the VCSELs 810 respectively include a pair of (n-type and p-type) distributed Bragg reflectors (DBRs) 810n and 810p. The DBRs 810n, 810p provide the mirrors for a resonant cavity that contains the layer(s) of the active region 810a of each VCSEL 810, which in some embodiments include multiple quantum well (MQW) structures.

Emitters or emitter arrays in accordance with embodiments of the present invention may be top- or frontside-emitting (with light emission in a direction away from or opposite to the semiconductor device layer or wafer), or may be back- or backside-emitting (with light emission in a direction toward or so as to pass through the semiconductor device layer or wafer, which is optically transparent to the wavelength(s) of light emission). FIG. 8A illustrates an illumination apparatus 800a including an integrated frontside illumination (FSI) VCSEL array and stacked driver IC configuration in accordance with some embodiments of the present invention. FIG. 8B illustrates an illumination apparatus 800b including an integrated backside illumination (BSI) VCSEL array and stacked driver IC configuration in accordance with some embodiments of the present invention.

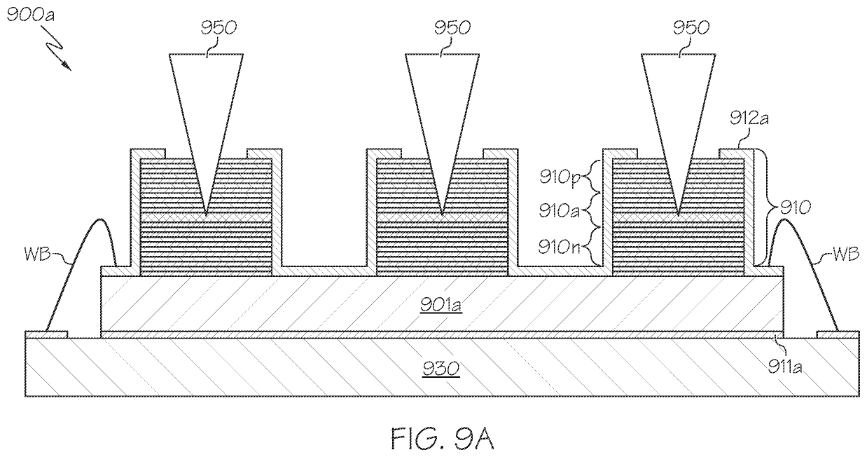

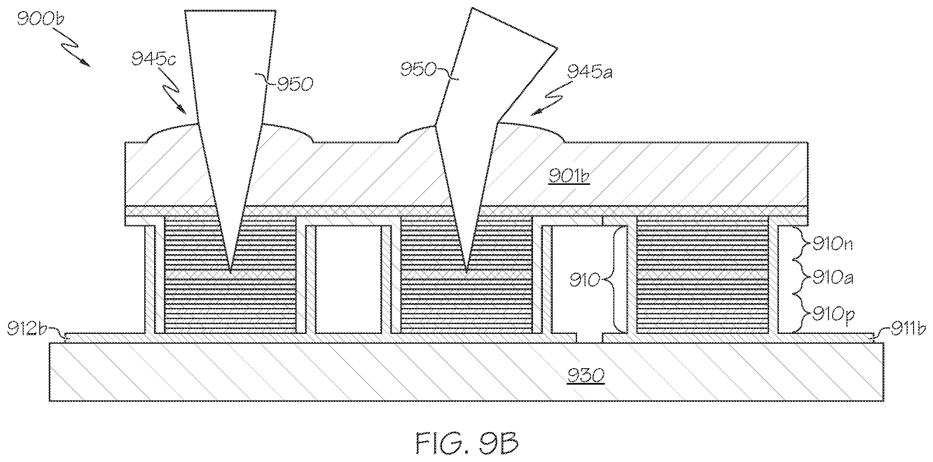

As shown in the illumination apparatus of FIG. 8A, the VCSELs 810 of the VCSEL wafer 801a are oriented in a top-emitting or frontside illumination configuration, where the light output 850 from the VCSELs 810 is emitted from the top of the wafer 801a. More particularly, the lasing apertures of the VCSELs 810 are oriented to emit light in a direction opposite to the VCSEL wafer or substrate 801a, which is stacked on the driver transistor wafer 802a. The driver circuitry of the driver transistor wafer 802a is electrically connected to respective VCSELs 810 (e.g., to respective anode connections 811 of respective VCSELs 810 or sub-arrays of VCSELs 815a) at the bonding interface 803a by respective TSVs 804a extending through the VCSEL wafer 801a. The driver transistor wafer 802a is electrically connected to the PCB 830 by respective TSVs 804c extending through the driver wafer 802a (e.g., to common cathode connections of respective VCSELs 810 or sub-arrays of VCSELs 815a). In contrast, in the illumination apparatus 900a shown in FIG. 9A that provides light output 950 through a top-emitting VCSEL structure, wire bonds WB outside the VCSEL area are required for electrical connection between the cathodes 912 of the VCSELs 910 and the submount 930, with an anode contact 911a between the VCSEL substrate 901a and the submount 930.

As shown in the illumination apparatus 800b of FIG. 8B, the VCSELs 810 of the VCSEL wafer 801b are oriented in a back-emitting or backside illumination configuration, where the light output 850 from the VCSELs 810 is emitted through the VCSEL wafer 801b and from the back of the VCSEL wafer 801b. More particularly, the lasing apertures of the VCSELs 810 are oriented to face and emit light toward the VCSEL wafer or substrate 801b (which is transparent to the wavelengths of light emission) such that the light emission 850 from the VCSELs 810 is transmitted through the VCSEL wafer or substrate 801b. The driver transistor wafer 802b is stacked on the VCSEL wafer 801b opposite the lasing apertures, such that the VCSELs 810 are between the VCSEL wafer 801b and the bonding interface 803b. Driver circuitry in the driver transistor wafer 802b is electrically connected to respective VCSELs 810 of the VCSEL wafer 801b at the bonding interfaces 803b by individual bump-bonds 804b (e.g., to respective anode connections 811b of respective VCSELs 810 or sub-arrays of VCSELs 815b). The driver transistor wafer 802b is electrically connected to the PCB 830 by respective TSVs 804c extending through the driver wafer 802b (e.g., to common cathode connections 812b of respective VCSELs or sub-arrays of VCSELs, also at the bonding interface 803b).

In some instances, the back-emitting configuration of the illumination apparatus 800b may offer greater flexibility in VCSEL array design. For example, the heterostructure shown in FIG. 8B may be grown up-side down (as compared to the top-emitting configuration shown in FIG. 8A), and respective layers 810n, 810p within the laser structure 810 may be used to provide electrical connections to the anode 811b and cathode 812b. No wire bonds are required, and in some instances, lenses can be monolithically etched into the surface of the substrate of the VCSEL wafer 801b opposite the VCSELs 810, for example, to reduce beam divergence (e.g., via a centered micro lens 945c as shown in FIG. 9B) or shift the output angle of the beam (e.g., via an offset micro lens 945o as shown in FIG. 9B).

As shown by way of comparison in the illumination apparatus 900b shown in FIG. 9B that provides light output 950 through the VCSEL wafer 901b in a back-emitting configuration, the absence of wire bonds in an illumination apparatus 800b according to some embodiments of the present invention can allow the back-emitting VCSEL dies 910 to be tiled close to one another to form larger and/or more dense illumination modules that may provide greater power output, for example, sufficient power for long-range sensing applications. In addition, eliminating the wire bonds can reduce the parasitic impedance of the package, and in turn can speed rise and fall times, which may improve performance, for example, for pulsed depth-sensing applications. In contrast, the VCSEL dies 910 of FIG. 9B are flip-chip bonded to a submount 930 that has the required electrical connections for the anode 911b and cathode 912b defined on the submount 930. As such, the structure 900b of FIG. 9B may not provide the greater VCSEL density (e.g., as provided by array interconnections between devices within the respective semiconductor layers) or the reduced interconnection lengths (provided by the connections at the bonding interface) as provided by some embodiments of the present invention.

In some embodiments, the driver transistor wafer may be bonded to the emitter wafer by bump bonds (e.g., 804b) that are distributed within the die or wafer or on the periphery of the die through the front side of the wafer, or using through vias (such as TSVs) and/or conductive bump bonds at the bottom of the driver transistor wafer. The driver transistor wafer may be grinded or otherwise thinned prior to bonding with the VCSEL wafer. In some embodiments, one or more signal redistribution layers may be provided on top of the metal stack and/or at the bottom of the driver transistor wafer to facilitate efficient signal routing.

In some embodiments, the driver transistor wafer may be directly bonded to the emitter wafer, or the driver transistor wafer may be bonded to the emitter wafer using an interposer layer therebetween. The interposer may have a Coefficient of Thermal Expansion (CTE) which is between that of the driver transistor wafer and the emitter wafer substrate in order to reduce mechanically-induced stresses.

In some embodiments, the driver transistor array may be the same size as the emitter array, e.g., after singulation from bonded VCSEL and CMOS wafers. The interconnection between the driver transistor array and a PCB may be implemented by conductive bumps.

In some embodiments, the driver transistor array may be larger than the emitter array, e.g., after singulation from the bonded VCSEL and CMOS wafers. Wirebond pads may be provided on non-overlapping portions of the driver transistor array area, that is, on surface portions of the driver transistor array that extend beyond the emitter array stacked thereon. The interconnection between the driver transistor array and a PCB may be implemented by using wirebonds.

Some embodiments described herein may also be used with micro-transfer printing (MTP) techniques. For example, spacing between VCSELs or groups of VCSELs may be needed for thermal dissipation, but such spacing may require additional wafer area. In some embodiments, as shown for example in FIG. 8A, lift-off structures may be provided on the VCSEL wafer and/or on the driver transistor wafer, such that during MTP, a hybrid driver-plus-VCSEL unit (or groups or arrays of hybrid driver-plus-VCSEL units; also referred to herein as integrated emitter-electronics structures) may be lifted-off and placed on a different substrate (e.g., a third substrate 830 that is non-native to the VCSELs and/or driver transistors), where electrical interconnects may be formed (e.g., at the bottom of a respective driver unit, which would no longer be a driver IC). Alternatively, the electrical interconnects may be provided through the top plane through the VCSEL unit, e.g., by using TSVs.

Advantages provided by embodiments of the present invention may include (but are not limited to): reduced resistance (R), inductance (L), and/or capacitance (C) in the electrical interconnects to the emitter anodes and/or cathodes from external circuit supplies, electrical grounds, and/or driver circuits, thereby improving emitter rise and fall times; reduced R, L, and/or C from the driver circuits to the ground/supplies, also improving rise/fall times of the emitter outputs; matching of rise and fall times within the emitter array using an integrated signal distribution system in the driver wafer; integration of programmable addressing of the emitter array, allowing selection and simultaneous addressing of selected emitters (e.g., multiple emitters in parallel, clusters of emitters, or individually); and integration of a heat sink (e.g., using TSVs to the PCB), thereby reducing the operating temperature of the emitters and allowing for higher power operation in a die format. As mentioned, while described primarily herein with reference to laser diodes (and specifically VCSELs), it will be understood that the emitters described herein are not limited to laser diodes, and may include other types of surface-emitting light sources (or even edge-emitting light sources) provided in one semiconductor layer that can be stacked and bonded with control circuits therefor in another semiconductor layer.

Embodiments of the present disclosure can be applied in lidar systems, illumination systems (such as vehicle headlights) and/or other illumination imagers that may use arrays of discrete emitters, such as LEDs or VCSELs, which may be generally referred to herein as illumination apparatus. Lidar systems and arrays described herein may be applied to ADAS (Advanced Driver Assistance Systems), autonomous vehicles, UAVs (unmanned aerial vehicles), industrial automation, robotics, biometrics, modelling, augmented and virtual reality, 3D mapping, and security. In some embodiments, the emitter elements of the emitter array may be VCSELs. In some embodiments, the emitter array may include a non-native (e.g., curved or flexible) substrate having thousands of discrete emitter elements electrically connected in series and/or parallel thereon.

Various embodiments have been described herein with reference to the accompanying drawings in which example embodiments are shown. These embodiments may, however, be embodied in different forms and should not be construed as limited to the embodiments set forth herein. Rather, these embodiments are provided so that this disclosure is thorough and complete and fully conveys the inventive concept to those skilled in the art. Various modifications to the example embodiments and the generic principles and features described herein will be readily apparent. In the drawings, the sizes and relative sizes of layers and regions are not shown to scale, and in some instances may be exaggerated for clarity.

The example embodiments are mainly described in terms of particular methods and devices provided in particular implementations. However, the methods and devices may operate effectively in other implementations. Phrases such as “example embodiment”, “one embodiment” and “another embodiment” may refer to the same or different embodiments as well as to multiple embodiments. The embodiments will be described with respect to systems and/or devices having certain components. However, the systems and/or devices may include fewer or additional components than those shown, and variations in the arrangement and type of the components may be made without departing from the scope of the inventive concepts.

The example embodiments are also described in the context of particular methods having certain steps or operations. However, the methods and devices may operate effectively for other methods having different and/or additional steps/operations and steps/operations in different orders that are not inconsistent with the example embodiments. Thus, the present inventive concepts are not intended to be limited to the embodiments shown, but are to be accorded the widest scope consistent with the principles and features described herein.

It will be understood that when an element is referred to or illustrated as being “on,” “connected,” or “coupled” to another element, it can be directly on, connected, or coupled to the other element, or intervening elements may be present. In contrast, when an element is referred to as being “directly on,” “directly connected,” or “directly coupled” to another element, there are no intervening elements present.

It will also be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The terminology used in the description of the invention herein is for the purpose of describing particular embodiments only and is not intended to be limiting of the invention. As used in the description of the invention and the appended claims, the singular forms “a”, “an” and “the” are intended to include the plural forms as well, unless the context clearly indicates otherwise.

It will also be understood that the term “and/or” as used herein refers to and encompasses any and all possible combinations of one or more of the associated listed items. It will be further understood that the terms “include,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to illustrations that are schematic illustrations of idealized embodiments (and intermediate structures) of the invention. As such, variations from the shapes of the illustrations as a result, for example, of manufacturing techniques and/or tolerances, are to be expected. Thus, the regions illustrated in the figures are schematic in nature and their shapes are not intended to illustrate the actual shape of a region of a device and are not intended to limit the scope of the invention.

Unless otherwise defined, all terms used in disclosing embodiments of the invention, including technical and scientific terms, have the same meaning as commonly understood by one of ordinary skill in the art to which this invention belongs, and are not necessarily limited to the specific definitions known at the time of the present invention being described. Accordingly, these terms can include equivalent terms that are created after such time. It will be further understood that terms, such as those defined in commonly used dictionaries, should be interpreted as having a meaning that is consistent with their meaning in the present specification and in the context of the relevant art and will not be interpreted in an idealized or overly formal sense unless expressly so defined herein. All publications, patent applications, patents, and other references mentioned herein are incorporated by reference in their entireties.

Many different embodiments have been disclosed herein, in connection with the above description and the drawings. It will be understood that it would be unduly repetitious and obfuscating to literally describe and illustrate every combination and subcombination of these embodiments. Accordingly, the present specification, including the drawings, shall be construed to constitute a complete written description of all combinations and subcombinations of the embodiments of the present invention described herein, and of the manner and process of making and using them, and shall support claims to any such combination or subcombination.

Although the invention has been described herein with reference to various embodiments, it will be appreciated that further variations and modifications may be made within the scope and spirit of the principles of the invention. Although specific terms are employed, they are used in a generic and descriptive sense only and not for purposes of limitation, the scope of the present invention being set forth in the following claims.

1. An illumination apparatus, comprising:
a first semiconductor layer comprising a plurality of emitters that are electrically interconnected in or on the first semiconductor layer; and
a second semiconductor layer bonded to the first semiconductor layer in a stacked arrangement, the second semiconductor layer comprising a plurality of transistors that are electrically connected to respective emitters or subsets of the plurality of emitters at a bonding interface between the first and second semiconductor layers.

2. The illumination apparatus of claim 1, wherein the bonding interface comprises anode and/or cathode connections to the respective emitters or subsets, and wherein the transistors define respective control circuits that are electrically connected to the anode and/or cathode connections.

3. The illumination apparatus of claim 2, wherein the respective control circuits comprise driver circuits, and wherein each of the driver circuits is electrically connected to the anode or cathode connections of the respective emitters or subsets at the bonding interface.

4. The illumination apparatus of claim 3, wherein the respective emitters or subsets are electrically interconnected by array interconnects to define a two-dimensional array of the respective emitters or subsets, and wherein the driver circuits define a two-dimensional array of the driver circuits that are electrically connected to the two-dimensional array of the respective emitters or subsets, respectively, at the bonding interface.

5. The illumination apparatus of claim 3, further comprising a signal distribution circuit that is electrically connected to the driver circuits and is configured to control timings of respective drive signals output from the driver circuits.

6. The illumination apparatus of claim 3, further comprising an addressing circuit that is configured to address the driver circuits to individually select one of the respective emitters or subsets at a time.

7. The illumination apparatus of claim 6, wherein the respective control circuits of the second semiconductor layer comprise the signal distribution circuit and/or the addressing circuit.

8. The illumination apparatus of claim 1, further comprising:
one or more additional circuits configured to provide localized decoupling capacitance, power supply routing, and/or other control of the respective emitters or subsets,
wherein the one or more additional circuits is in the second semiconductor layer or is in a third semiconductor layer that is stacked on and bonded to the second semiconductor layer opposite the first semiconductor layer.

9. The illumination apparatus of claim 2, wherein the bonding interface between the first and second semiconductor layers comprises hybrid bonding, through vias, and/or bump-bonds that electrically connect the anode and/or cathode connections to the control circuits and/or to an electrical ground.

10. The illumination apparatus of claim 4, wherein the array interconnects electrically connect the subsets within the first semiconductor layer in series or parallel with respective interconnection lengths of less than about 10 microns.

11. The illumination apparatus of claim 1, wherein the first and second semiconductor layers comprise first and second semiconductor wafers that are bonded to one another, wherein the plurality of emitters are native to the first semiconductor wafer and the plurality of transistors are native to the second semiconductor wafer.

12. The illumination apparatus of claim 10, wherein the first and second semiconductor layers comprise singulated portions of first and second semiconductor wafers that are bonded to one another and define respective integrated emitter-electronics structures.

13. The illumination apparatus of claim 1, wherein the transistors are directly connected with the anodes and/or cathode connections of the respective emitters or subsets at the bonding interface.

14. The illumination apparatus of claim 1, wherein the bonding interface comprises one or more interposer or redistribution layers between the first and second semiconductor layers.

15. The illumination apparatus of claim 1, wherein the first semiconductor layer is between the emitters and the bonding interface, and the emitters comprise respective lasing apertures that are opposite the first semiconductor layer.

16. The illumination apparatus of claim 1, wherein the emitters are between the first semiconductor layer and the bonding interface, and the emitters comprise respective lasing apertures that are facing the first semiconductor layer.

17. A method of fabricating an illumination apparatus, the method comprising:
providing a first semiconductor layer comprising a plurality of emitters that are electrically interconnected in or on the first semiconductor layer;
providing a second semiconductor layer comprising a plurality of transistors; and
bonding the second semiconductor layer to the first semiconductor layer in a stacked arrangement, wherein the transistors are electrically connected to respective emitters or subsets of the plurality of emitters at a bonding interface between the first and second semiconductor layers.

18. The method of claim 17, wherein the first and second semiconductor layers comprise first and second semiconductor wafers that are bonded to one another, wherein the plurality of emitters are native to the first semiconductor wafer and the plurality of transistors are native to the second semiconductor wafer.

19. The method of claim 18, further comprising:
singulating bonded portions of the first and second semiconductor layers into respective integrated emitter-electronics structures,
optionally wherein the second semiconductor wafer is thinned prior to the bonding.

20. The method of claim 19, wherein the portions of the first and/or second semiconductor layers comprise respective lift-off structures, and further comprising:
transfer-printing one or more of the respective integrated emitter-electronics structures on a third substrate that is non-native to the emitters and/or transistors,
optionally wherein the third substrate comprises electrical interconnects thereon.

21. The method of claim 17, wherein the bonding interface comprises anode and/or cathode connections to the respective emitters or subsets, and wherein the transistors define respective control circuits that are electrically connected to the anode and/or cathode connections.

22. The method of claim 21, wherein the respective control circuits comprise driver circuits, and wherein each of the driver circuits is electrically connected to the anode or cathode connections of the respective emitters or subsets at the bonding interface.

23. The method of claim 22, wherein the respective emitters or subsets are electrically interconnected by array interconnects to define a two-dimensional array of the respective emitters or subsets, and wherein the driver circuits define a two-dimensional array of the driver circuits that are electrically connected to the two-dimensional array of the respective emitters or subsets, respectively, at the bonding interface.

24. The method of claim 22, wherein the respective control circuits further comprise a signal distribution circuit that is electrically connected to the driver circuits and is configured to control timings of respective drive signals output from the driver circuits.

25. The method of claim 22, wherein the respective control circuits further comprise an addressing circuit that is configured to address the driver circuits to individually select one of the respective emitters or subsets at a time.

26. The method of claim 21, further comprising:
providing one or more additional circuits configured to provide localized decoupling capacitance, power supply routing, and/or other control of the respective emitters or subsets,
wherein the one or more additional circuits is in the second semiconductor layer or is in a third semiconductor layer that is stacked on and bonded to the second semiconductor layer opposite the first semiconductor layer.

27. The method of claim 21, wherein the bonding comprises:
bonding the second semiconductor layer to the first semiconductor layer using hybrid bonding, through vias, and/or bump-bonds at the bonding interface to electrically connect the anode and/or cathode connections to the control circuits and/or to an electrical ground.

28. The method of claim 23, wherein the array interconnects electrically connect the subsets within the first semiconductor layer in series or parallel with respective interconnection lengths of less than about 10 microns.

29. The method of claim 21, wherein the bonding comprises:
directly connecting the transistors with the anodes and/or cathode connections of the respective emitters or subsets at the bonding interface.

30. The method of claim 21, wherein the bonding comprises:
bonding the second semiconductor layer to the first semiconductor layer with one or more interposer or redistribution layers between the first and second semiconductor layers.

31. The method of claim 17, wherein the first semiconductor layer is between the emitters and the bonding interface, and the emitters comprise respective lasing apertures that are opposite the first semiconductor layer.

32. The method of claim 17, wherein the emitters are between the first semiconductor layer and the bonding interface, and the emitters comprise respective lasing apertures that are facing the first semiconductor layer.
